(19) United States
(12) Patent Application Publication
(10) Pub. No.: US 2013/0037855 A1
(43) Pub. Date: Feb. 14, 2013

(54) SI-GE LAMINATED THIN FILM AND INFRARED SENSOR USING SAME

(71) Applicants: Shoji Sekino, Tokyo (JP); Shin Nakamura, Tokyo (JP); Tsutomu Yoshitake, Tokyo (JP); Akio Furukawa, Tokyo (JP)

(72) Inventors: Shoji Sekino, Tokyo (JP); Shin Nakamura, Tokyo (JP); Tsutomu Yoshitake, Tokyo (JP); Akio Furukawa, Tokyo (JP)

(73) Assignee: NEC CORPORATION, Tokyo (JP)

(21) Appl. No.: 13/643,223

(22) PCT Filed: Mar. 25, 2011
(86) PCT No.: PCT/JP2011/058374

§ 371 Date: Oct. 24, 2012

(30) Foreign Application Priority Data
Apr. 27, 2010 (JP) 2010-101692

(51) Int. Cl. B32B 7/02; H01L 31/028

(52) U.S. Cl. 257/184; 428/213; 257/E31.012

(57) ABSTRACT

Provided is a Si—Ge laminated thin film including at least one Si layer and at least one Ge layer, which are alternately laminated on a substrate (1). A Si layer (31) and a Ge layer (22) each have a thickness in a range of 5 to 500 nm. The Si layer (31) is amorphous and only the Ge layer (22) is crystallized. An average crystallite size of Ge in the Ge layer (22) is 20 nm or less.

### TECHNICAL FIELD

This invention relates to an infrared sensor, and more particularly, to a Si—Ge laminated thin film suitable for a bolometer material to be used for a bolometer type infrared sensor.

### BACKGROUND ART

All substances emit infrared radiation resulting from the temperatures of the substances. A device which senses the infrared radiation and thereby detects the temperature of an object of observation is generally referred to as “infrared sensor”. Such infrared sensors are arrayed at a microlevel to be used in an infrared imaging technology. By using the infrared imaging technology, the temperature of the object of the observation may be visualized, and thus, video images may be taken out even in a dark field such as one during the night. Therefore, the infrared imaging technology has become a technology essential to a security camera, a surveillance camera, or the like. Further, in recent years, the infrared imaging technology has attracted attention also from the viewpoint of its application for distinguishing a person who has a fever caused by influenza or the like.

Infrared radiation is a generic name for electromagnetic waves in a region of wavelengths longer than visible radiation, and wavelength ranges used by an infrared sensor are roughly broken into near-infrared radiation (up to about 3 μm), mid-infrared radiation (about 3 to 8 μm), and far-infrared radiation (about 8 to 14 μm).

In particular, far-infrared radiation is important for an infrared sensor for observing a human life environment because far-infrared radiation is less absorbed by the atmosphere, a human body temperature emits far-infrared radiation in the vicinity of 10 μm at body temperature, and the like.

As a material for an infrared sensor, a quantum infrared sensor having a sensor material of HgDdTe has been widely used. However, when such a quantum infrared sensor is used, the temperature of the device is required to be lowered at least to liquid nitrogen temperature (77 K), and thus, a cooling system for cooling the device is required, which limits downsizing of the device.

Therefore, in recent years, an uncooled infrared sensor which does not need to cool the device to a low temperature is widespread. As the uncooled infrared sensor, a bolometer the principle of which is to detect change in electrical resistance that accompanies change in temperature of the device is widely used. In particular, a material obtained by forming a thin film of vanadium oxide (hereinafter, abbreviated as VO_{X}), amorphous Si, or the like is commercialized and widely available.

Indices of performance of a bolometer include some parameters. Among such parameters, in particular, the electrical resistance change factor per degree of temperature change (value obtained by dividing resistance change per temperature change by the resistance value) referred to as Temperature Coefficient of Resistance (TCR) and resistivity are important parameters. Specifically, a material having a TCR the absolute value of which is large and having a low resistivity is demanded. As a material to be used in a bolometer, a material which exhibits semiconductive properties is suitable, and the TCR thereof is a negative value.

As VO_{X} used in an uncooled bolometer at present, VO_{X} having a TCR which exceeds about −4%/K at room temperature is reported (see, for example, Japanese Unexamined Patent Application Publication (JP-A) No. 2000-143243 (corresponding to U.S. Pat. No. 6,489,613) (hereinafter, referred to as “Patent Document 1”)). With regard to a mass produced product level, VO_{X} having a TCR of −1.5%/K is used. However, there are various crystal phases in VO_{X}, each of which exhibits its own particular properties. Under present circumstances, when infrared sensor devices using VO_{X} are arrayed, it cannot be said that unevenness in performance is not necessarily sufficiently small even among arrays within one wafer, because, for example, it is difficult to cause the mixture ratio of the various crystal phases to be constant.

Further, when a film of VO_{X} is formed, it is necessary to introduce not an ordinary silicon process but a dedicated process. Therefore, there is a limitation that the production line itself is required to be dedicated to VOₓ. Further, adverse effects on wiring and the like due to the necessity of causing the annealing temperature to be 400° C. or higher and the like are also feared.

Further, during the 1990s, there was developed in which a bolometer a device material thereof was amorphous Si that could be totally manufactured in a silicon process. The manufacturing process of amorphous Si may be simplified, and thus, amorphous Si is advantageous from the viewpoint of costs. However, there is a problem that the resistivity is incomparably higher.

Against this backdrop, a bolometer in which a device material thereof is polycrystalline silicon-germanium (hereinafter, referred to as p-SiGe) has been also developed and commercialized (see, for example, Japanese Unexamined Patent Application Publication (JP-A) No. Hei 11-40824 (corresponding to U.S. Pat. No. 6,194,722) (hereinafter, referred to as “Patent Document 2”)). However, VO_{X} and amorphous Si are mainstream in the present market for uncooled bolometers, and p-SiGe is not widely available as yet. p-SiGe has a problem that, although its TCR is large, its resistivity is high. Further, a small difference in composition ratio between Si and Ge affects the unevenness in performance, and thus, it is necessary to strictly control the composition in vapor-phase growth by CVD. Further, it is necessary to raise the annealing temperature to about 650° C., and thus, there is also a demerit that other portions forming the device are liable to be adversely affected.

Further, it is also a problem that crystal distortion of p-SiGe is large, and thus, the thin film itself is liable to be deformed by annealing after the film is formed. Therefore, a method of alleviating distortion due to the crystal structure when p-SiGe is used has been searched for (see, for example, Japanese Unexamined Patent Application Publication (JP-A) No. 2007-165927 (corresponding to U.S. Pat. No. 7,075,081) (hereinafter, referred to as “Patent Document 3”)). However, under present circumstances, there is no perfect solution thereto.

Further, an idea is provided with regard to a thermal sensor using a superlattice structure in which Si and Ge are laminated (see, for example, Japanese Unexamined Patent Application Publication (JP-A) No. 2008-70353 (corresponding to U.S. Pat. No. 7,442,599) (hereinafter, referred to as “Patent Document 4”)). In Patent Document 4, with regard to a Si layer and a Ge layer, each of the film thicknesses is defined to be in a range of 2 to 50 nm and the number of units of the Si—Ge layer to be repeatedly formed is defined to be in a range of 10 to 100. However, in Patent Document 4, there is no definite reference to the crystal states of Si and Ge in the layered structure.

As described above, p-SiGe has the following problems.

With regard to p-SiGe, when the TCR is increased, the resistivity becomes higher, and when the resistivity is decreased, the TCR becomes smaller, and thus, it is difficult to set optimum conditions with regard to the composition ratio and the annealing conditions.

The crystal structure of p-SiGe is liable to be distorted, and thus, is liable to be deformed due to internal stress caused by annealing treatment after the device is formed or the like. In particular, it is necessary to raise the annealing temperature to about 1,000° C., and thus, wiring and the like which form the device are adversely affected.

In order to form a film of p-SiGe, it is necessary to use CVD, but the equipment is expensive, which leads to increase in the manufacturing cost. It is also possible to carry out sputtering or the like in forming a film of p-SiGe, but there are problems including difficulty in strictly controlling the composition.

In p-SiGe, the crystal structure of Si and the crystal structure of Ge are the same and a complete solid solution is formed, and thus, it is difficult to control the composition to be uniform within a large diameter wafer.

Other prior art documents related to this invention is further known.

For example, Japanese Unexamined Patent Application Publication (JP-A) No. 2003-282977 (hereinafter, referred to as “Patent Document 5”) discloses a manufacturing method in which a Si—Ge laminated film is formed by sputtering.

Patent Document 5 only discloses an ordinary technology of manufacturing a SeGe laminated film by sputtering.

Further, Japanese Unexamined Patent Application Publication (JP-A) No. Hei 03-284882 (hereinafter, referred to as “Patent Document 6”) discloses a superlattice structure in which an a-Si layer and a polycrystalline germanium layer are alternately laminated. In Patent Document 6, a-Si and a-Ge are alternately laminated. The solid phase growth temperature of a-Si is 500° C. while the solid phase growth temperature of a-Ge is 300° C. After a-Si and a-Ge are laminated, by carrying out thermal annealing treatment at a relatively low temperature (300 to 400° C.), only a-Ge undergoes solid phase growth to form the polycrystalline germanium layer. In this way, the a-Si layer and the polycrystalline germanium layer are alternately laminated. Patent Document 6 also discloses that, after the lamination is formed, a vacuum chamber is filled with a nitrogen (N₂) atmosphere, the temperature in the chamber is held at 300° C., and annealing is carried out for five hours.

Patent Document 6 discloses prior art of a laminated film (superlattice) of an ordinary semiconductor amorphous Si/crystallized Ge, and also refers to treatment such as annealing. However, Patent Document 6 does not refer to a specific size of the Ge crystal structure.

### SUMMARY OF THE INVENTION

### Problem to be Solved by the Invention

It is an object of this invention to provide a Si—Ge material, which can be made at a lower cost with higher reliability that in a conventional case and has a large TCR and a low resistance value, by carrying out annealing treatment at a relatively low temperature to a Si—Ge laminated film formed using sputtering which may be controlled at a relatively low cost.

### Means to Solve the Problem

According to this invention, there is provided a Si—Ge laminated thin film, including at least one Si layer and at least one Ge layer, which are alternately laminated on a substrate, in which: the at least one Si layer and the at least one Ge layer each have a thickness in a range of 5 to 500 nm; the at least one Si layer is amorphous and only the at least one Ge layer is crystallized; and an average crystallite size of Ge in the at least one Ge layer is 20 nm or less.

### Effect of the Invention

According to this invention, the average crystallite size of Ge in the Ge layer is 20 nm or less, and thus, a large TCR is maintained, and still, the electrical resistance may be lowered.

### BRIEF DESCRIPTION OF THE DRAWINGS

FIG. 1 is a sectional view illustrating a Si—Ge laminated thin film according to a first exemplary embodiment of this invention;

FIG. 2 is a sectional view illustrating a Si—Ge laminated thin film according to a second exemplary embodiment of this invention;

FIG. 3 is a sectional view illustrating a Si—Ge laminated thin film according to a third exemplary embodiment of this invention;

FIG. 4 is a sectional view illustrating a conventional p-SiGe film;

FIG. 5 is a plan view illustrating electrodes provided on a surface of a sample;

FIG. 6 shows SEM images of sections of samples, the SEM images each showing a quartz substrate on the left side and a surface on the right side;

FIG. 7 is a graph showing Raman spectra of the samples;

FIG. 8 is a graph showing X-ray diffraction spectra of the samples;

FIG. 9 is a graph showing X-ray diffraction spectra of samples in which a Si single layer film and a Ge single layer film are annealed;

FIG. 10 is a table of lattice constants and crystallite sizes of the samples; and

FIG. 11 is a table of the results of electrical measurement of the samples.

### MODE FOR EMBODYING THE INVENTION

Structures and manufacturing methods of an infrared sensor material according to exemplary embodiments of this invention are described in detail in the following. However, the structures and configuration exemplified in the exemplary embodiments of this invention are only examples for causing the effects thereof to manifest themselves and the structures and the configurations are not limited to those which are described before or in the following.

### (Method of Manufacturing Thin Film)

As a method of manufacturing a thin film, sputtering, CVD, a sol-gel method, or the like may be used. In particular, sputtering has a merit that the interface between Si and Ge is clear, and thus, diffusion of atoms at the interface due to annealing treatment is less liable to occur. Therefore, sputtering is most preferred as the method of forming the film according to exemplary embodiments of this invention. With regard to sputtering, there is no specific limitation, but, in order that a reaction such as oxidation or nitriding may be less liable to occur in sputtering, it is desired that the vacuum before the film is formed be reduced to at least 10⁻³ Torr or lower, more preferably 10⁻⁶ Torr or lower.

It is preferred that a Si layer has electrical conductivity to some extent, and thus, it is preferred to use a target having B or the like doped therein. However, if B or the like is doped too much, the electrical resistance may be lowered too much, and thus, the TCR may be reduced. Therefore, it is desired to use a Si target having a resistivity in a range of 10⁻³ to 10² Ω·cm by controlling the amount of the doped B or the like. However, in sputtering, the amount of B vapor-deposited on a substrate is not necessarily in proportion to the amount of the doped B, and thus, it is not necessary to strictly determine the doped amount.

In a Si—Ge thin film, electrical conduction in a Ge layer is dominant, and thus, it is necessary that the resistivity of the Ge layer be sufficiently lower compared with that of the Si layer. Therefore, a target having As, Sb, or the like doped therein may be used. However, a sufficiently low resistivity may be obtained by microcrystallizing Ge itself and the electrical conduction may be affected when the doped element is precipitated, and thus, it is desired that a Ge target with no element doped therein be used. However, it is not necessary to strictly determine whether there is a doped element or not and the resistivity of the target. Further, the temperature of the substrate when the film is formed is not specifically limited, either, but it is desired that the stage of the sputtering be carried out at room temperature in order to prevent crystallization.

Note that, the temperature of the substrate may be set at 200 to 550° C. when the Si layer and the Ge layer are laminated. In this case, crystallization may be carried out at the stage of the film formation, and thus, the annealing process may be eliminated.

### (Si—Ge Laminated Thin Film)

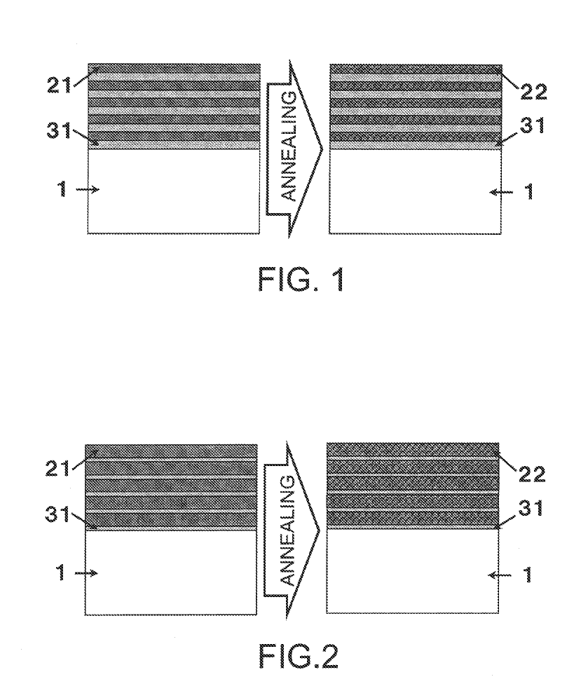

As illustrated in FIG. 1, it is enough that the Si—Ge thin film has a structure in which a Si layer 31 and a Ge layer 21 are alternately laminated on a substrate 1. However, with regard to the Ge layer, as described below, microcrystallization 22 thereof is essential. Further, lamination may be carried out not only so as to obtain a complete planar shape, but may be carried out also on a surface having a curvature or on a polyhedron having a number of faces, and it is not necessary to impose limitations on the substrate 1 or a body on which the vapor deposition is carried out.

The thicknesses of the Si layer 31 and the Ge layer 22 are not specifically limited, but it is preferred that both of the thicknesses be in a range of about 5 to 500 nm. However, when, for example, the Si layer 31 is thin, there is a possibility that a pinhole is formed therein or that leakage current flows due to tunneling currents. Further, when the Ge layer 22 is thin, there is a possibility that sufficient electrical conduction cannot be obtained, but, when the film thickness is too large, there is a possibility that crystallization of the Ge layer 22 breaks the Si layer 31. Therefore, the film thicknesses are preferably in a range of 10 to 250 nm, and more preferably, in a range of 25 to 125 nm.

It is desired that the Si layer 31 have an amorphous structure. However, if, when the film is formed, a part thereof is crystallized, it is not necessarily required that the Si layer 31 be in a fully amorphous state. Note that, the amorphous structure in the Si—Ge laminated film in the exemplary embodiments of this invention means that the crystallinity of Si in the Si layer is at least less than 10%.

It is desired that the Ge layer 22 be microcrystallized. Even when the Ge layer 22 is not microcrystallized when the film is formed, it is desired that, by annealing treatment thereafter, at least 70% or more of the structure be microcrystallized. Further, it is desired that the average crystallite size of Ge be in a range of 5 to 50 nm, and more preferably, it is desired that the average crystallite size of Ge be 20 nm or less. The average crystallite size which is presented here is calculated using Scherrer's equation from the half-width of a peak observed in an X-ray diffraction spectrum, and is a value derived from the results in examples described below. However, the crystallite size may also be estimated using an electron microscope such as a transmission electron microscope (TEM) or a scanning electron microscope (SEM).

In this case, the reason that the average crystallite size of Ge is set to 20 nm or less is as follows. If the crystallite size of Ge exceeds 20 nm, the electrical resistance may be lowered, but the TCR is also reduced. On the other hand, if the crystallite size of Ge is 20 nm or less, the electrical resistance is lowered, and still, the reduction in TCR is small (the TCR is maintained). Requirements which are desired for an infrared material are that the TCR thereof is large and the electrical resistance thereof is low. With regard to an ordinary material (structure), by lowering the electrical resistance, the TCR is reduced (trade-off relation). An ordinary Si—Ge laminated film has a similar tendency. Therefore, in the exemplary embodiments of this invention, the average crystallite size of Ge is set to 20 nm or less, and thus, an effect of lowering the electrical resistance while maintaining a large TCR may be obtained.

As illustrated in FIG. 2, the ratio between the thickness of the Si layer 31 and the thickness of the Ge layer 22 is not specifically limited, but it is preferred that the Ge layer 22 be thicker than the Si layer 31. The resistivity of the Si layer 31 is, even when the Si layer 31 is amorphous, higher than that of the Ge layer 22 by three orders of magnitude or more. Therefore, even when the Si layer 31 is sufficiently thin compared with the Ge layer 22, the effect of improving the TCR may be obtained. Specifically, it is preferred that the film thickness ratio of Si:Ge be in a range of 1:9 to 8:2, and more preferably, it is desired that Si:Ge be in a range of 2:8 to 5:5. With regard to these ranges of the numeric values, it is borne in mind that the ratio of Si:Ge of an infrared sensor using a p-SiGe thin film which is commercialized before is 7:3, but it is clearly indicated that the composition ratio is not necessarily appropriate also for the Si—Ge laminated film.

The number of the laminated Si layers and the number of the laminated Ge layers are not required to be specifically limited, but at least one Si layer and at least one Ge layer are laminated. Specifically, it is desired that the number of the laminated Si layers and the number of the laminated Ge layers are each in a range of 2 to 20, more preferably 3 to 10. These ranges of the numeric values are not to be strictly determined, but are set taking into consideration that, when 10 or more layers are laminated, the Si layers become electrical barriers, and thus, layers which are nearer to the substrate are less liable to contribute to the electrical characteristics such as the TCR and the resistivity.

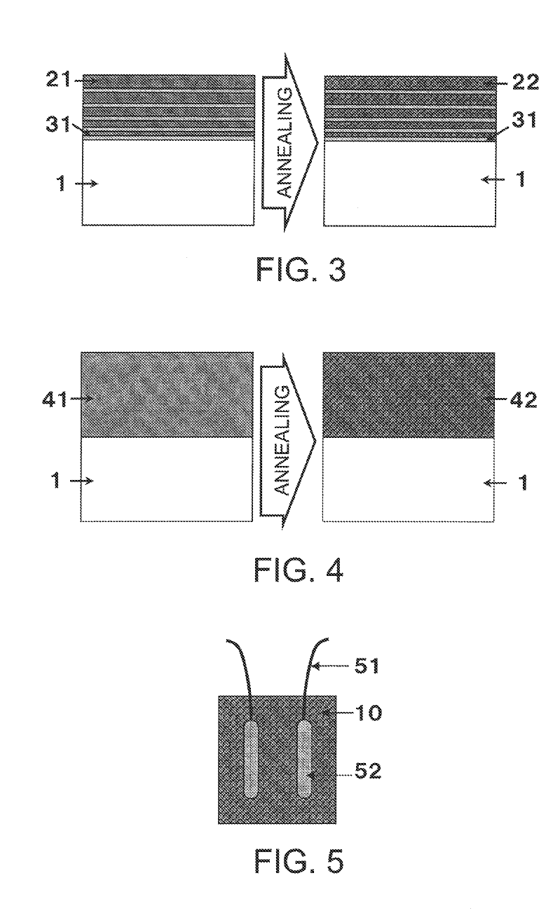

As illustrated in FIG. 3, it is not necessarily required that the ratio between the Si layer 31 and the Ge layer 22 be uniform within the laminated film, and the layers may be laminated with the thicknesses thereof being gradient, for example, the Si layer 31 may become relatively thinner as the layer goes up. However, no specific limitations are imposed on the layered structure.

### (Annealing of Si—Ge Laminated Thin Film)

It is desired that the annealing treatment of the Si—Ge thin film be carried out at 600° C. or lower. More preferably, it is desired that the annealing treatment be carried out at 550° C. or lower, and it is essential that at least Ge forming the Ge layer 22 may be microcrystallized. Further, the lower limit of the annealing temperature is not limited, but it is thought that a temperature which is 300° C. or higher is necessary, and thus, it is appropriate to carry out the annealing at a temperature in a range of 300 to 550° C. The annealing temperature presented here is lower as compared with the annealing temperature specified in Patent Document 3 above (600 to 700° C.), which indicates that members such as microwiring are less damaged.

The atmosphere of the annealing treatment is not specifically limited, but, in order to reduce the effect of oxidation, nitriding, or the like of Si and Ge, it is desired that the atmosphere be replaced by an inert gas such as Ar. Further, when, by taking out the thin film after being formed to the atmosphere, the activated surface of the thin film is exposed to an environment under the effect of oxidation, nitriding, or the like, it is desired that the annealing treatment be carried out in a reducing atmosphere. Further, pressure applied when the annealing is carried out is not specifically determined, but, in order to prevent an atmospheric gas from entering into the thin film, it is desired that the annealing be carried out not under excessive pressure but under normal atmospheric pressure or under a reduced pressure.

### (Forming Device of Si—Ge Laminated Thin Film)

The Si—Ge laminated thin film is used as a thermal resistance sensing portion of an infrared sensor having an appropriate structure, that is, as an infrared sensor material. The infrared sensor may be a single device type, or may be in the form of a two-dimensionally arranged array such as the form used in an image sensor. Further, the infrared sensor may also have a structure in which the sensor material is arranged on a curved surface or on a polyhedron.

The manufacturing process of the infrared sensor using the Si—Ge laminated thin film differs from a method of manufacturing a conventional infrared sensor only in the conditions of the film formation, and a conventional method may be used in other steps. Therefore, the manufacturing process may be easily applied to a microstructure such as a two-dimensional infrared image sensor using an infrared sensor.

### EXAMPLES

In the following, the Si—Ge laminated thin film according to this invention is specifically described by showing examples of this invention.

### Example 1

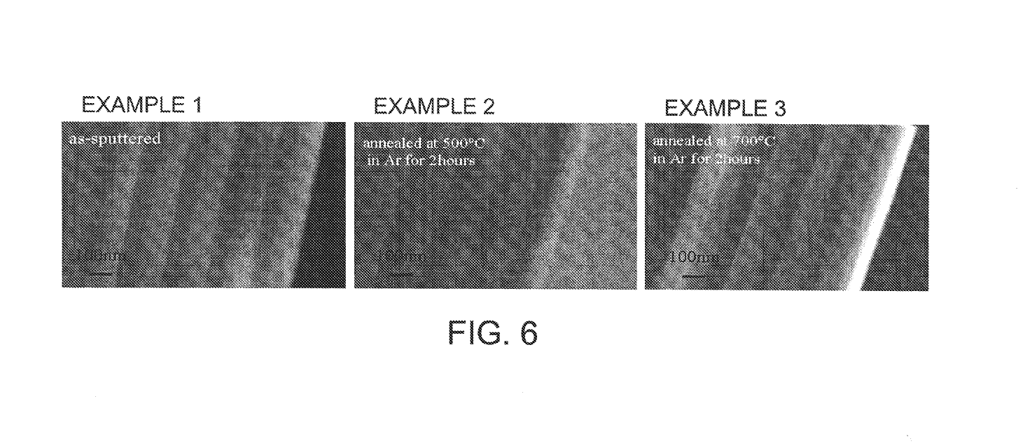

SiO₂ substrate 1 (hereinafter, referred to as quartz substrate 1) was put into an RF magnetron sputtering system (hereinafter, abbreviated as sputtering system), and the vacuum inside the system was set to 10⁻³ Torr or lower. As illustrated in FIG. 1, using as the standard a sputtering rate determined by a preliminary experiment, the a-Si layers 31 each having a thickness of 100 nm and the a-Ge layers 21 each having a thickness of 100 nm were alternately laminated to form a Si—Ge laminated thin film (having a thickness of 1 μm) including five a-Si layers 31 and five a-Ge layers 21. Note that, the Si target was doped with B, and the resistivity thereof was 10 Ω·cm or less. Further, the Si—Ge laminated thin film was formed so that the uppermost surface was the a-Ge layer 21. The sample of Example 1 is illustrated on the left side of FIG. 1. The sample was taken out of the sputtering system, and, as illustrated in FIG. 5, two conductors 51 each having a diameter of 0.2 mmφ were joined with In to a surface 10 of the sample which was taken out to form electrodes 52. The electrodes 52 were arranged parallel to each other. The distance between the electrodes was 0.5 mm, and the contact length of In was 5 mm.

### Example 2

A sample formed similarly to the case of Example 1 was put into a tubular electric furnace. After evacuation to 10⁻³ Torr or lower, the temperature was raised to 500° C. while causing an Ar gas to flow at 500 cm³/min, and the state was held for two hours. After that, cooling was carried out while causing an Ar gas to flow. After the temperature was lowered to 100° C. or lower, the sample was taken out. The sample of Example 2 is illustrated on the right side of FIG. 1. Electrodes were formed on the sample surface 10 similarly to the case of Example 1 (FIG. 5).

### Example 3

The temperature of a sample formed similarly to the case of Example 1 was raised to 700° C. under conditions which were the same as those of Example 2, and the state was held for two hours. After that, cooling was carried out while causing an Ar gas to flow. After the temperature was lowered to 100° C. or lower, the sample was taken out. Electrodes were formed on the sample surface 10 similarly to the case of Example 1 (FIG. 5).

### Comparative Example 1

The quartz substrate 1 was put into a sputtering system, and the vacuum inside the system was set to 10⁻³ Torr or lower. Using as the standard the sputtering rate determined by the preliminary experiment, a Ge layer was laminated by 1 μm to form a Ge single layer film. The sample was taken out of the sputtering system. Electrodes were formed on the sample surface 10 similarly to the case of Example 1.

### Comparative Example 2

A sample formed similarly to the case of Comparative Example 1 was put into a tubular electric furnace, and a sample which was annealed at 500° C. similarly to the case of Example 2 was formed. Electrodes were formed on the sample surface 10 similarly to the case of Example 1.

### Comparative Example 3

A sample formed similarly to the case of Comparative Example 1 was put into a tubular electric furnace, and a sample which was annealed at 700° C. similarly to the case of Example 3 was formed. Electrodes were formed on the sample surface 10 similarly to the case of Example 1.

### Comparative Example 4

The quartz substrate 1 was put into a sputtering system, and the vacuum inside the system was set to 10⁻³ Torr or lower. Using as the standard the sputtering rate determined by the preliminary experiment, a Si layer was laminated by 1 μm to form a Si single layer film. The sample was taken out of the sputtering system. Electrodes were formed on the sample surface 10 similarly to the case of Example 1.

### Comparative Example 5

A sample formed similarly to the case of Example 4 was put into a tubular electric furnace, and a sample which was annealed at 500° C. similarly to the case of Example 2 was formed. Electrodes were formed on the sample surface 10 similarly to the case of Example 1.

### Comparative Example 6

A sample formed similarly to the case of Example 4 was put into a tubular electric furnace, and a sample which was annealed at 700° C. similarly to the case of Example 3 was formed. Electrodes were formed on the sample surface 10 similarly to the case of Example 1.

### Comparative Example 7

The quartz substrate 1 was put into a sputtering system, and the vacuum inside the system was set to 10⁻³ Torr or lower. Using as the standard the sputtering rate determined by the preliminary experiment, a film of SiGe was formed by simultaneously sputtering Si and Ge so that the ratio there between was 7:3. The sample was taken out of the sputtering system and was put into a tubular electric furnace. After evacuation to 10⁻³ Torr or lower, the temperature was raised to 650° C. while causing an Ar gas to flow at 500 cm³/min, and the state was held for two hours. After that, cooling was carried out with Ar gas caused to flow. After the temperature was lowered to 100° C. or lower, the sample was taken out. A polycrystalline SiGe film (p-SiGe film) 42 manufactured in this way is illustrated on the right side of FIG. 4. An a-SiGe film 41 at the stage of the sputtering as illustrated on the left side of FIG. 4 was microcrystallized by the annealing to become the p-SiGe film 42. Electrodes were formed on the sample surface similarly to the case of Example 1.

### (Result of Experiment)

FIG. 6 shows SEM images of sections of the samples of Examples 1 to 3 described above. In FIG. 6, an image on the left side is a sectional view of the Si—Ge laminated film which was not annealed after the sputtering, an image in the center is a sectional view of the Si—Ge laminated film which was annealed at 500° C., and an image on the right side is a sectional view of the Si—Ge laminated film which was annealed at 700° C. The SEM images each show a state in which the quartz substrate 1 is on the left side and the Si layers and the Ge layers are laminated by turns on the surface thereof. The uppermost surface is the Ge layer, which is, in the plan view of FIG. 5, the Ge layer to which the electrodes are joined. It is difficult to see because the substrate is charged up, but, the lamination of the Si layers and the Ge layers are kept at 500° C. However, at 700° C., the interface between layers located on the front surface side and on the substrate side is becoming unclear, and it appears that Si atoms and Ge atoms are mutually diffused to some extent. Further, even in the case of the annealing at 700° C., it can be confirmed that the thin film structure is not deformed and almost no distortion is caused.

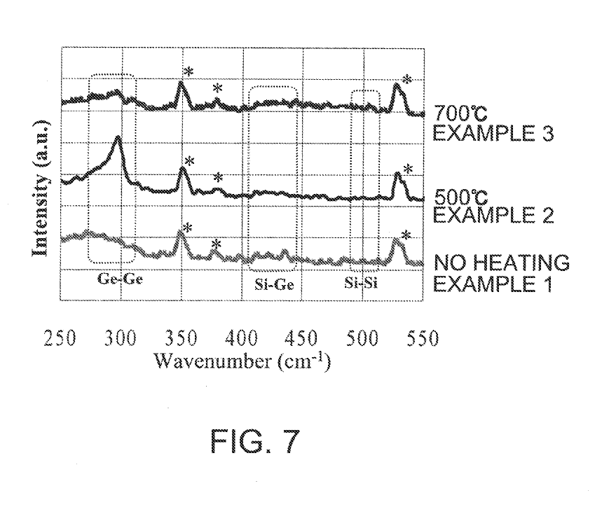

FIG. 7 shows Raman spectra of the samples of Examples 1 to 3. Peaks indicated by marks * are due to the quartz substrate 1 or the background. It may be confirmed that, in the case of no heating, peaks due to all bindings are unclear, but by annealing at 500° C., Ge—Ge binding considerably increases. At 500° C., peaks due to Si—Ge binding do not increase, and thus, Ge—Ge binding is thought to be formed on a priority basis by the annealing at 500° C. Peaks due to Ge—Ge binding decrease at 700° C. This is thought to be caused by mutual diffusion of Ge and Si assumed from the SEM images. Further, peaks due to Si—Si binding cannot be clearly seen even when the temperature reaches 700° C., which may be assumed to be because almost no diffusion of Si atoms occurs in the Si layers and the binding state does not change much.

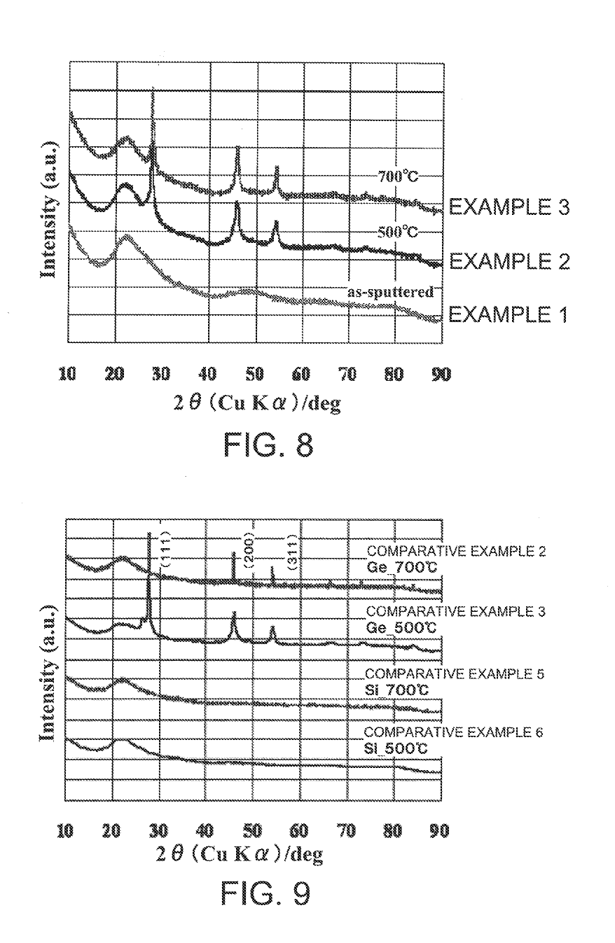

FIG. 8 shows X-ray diffraction spectra of the samples of Examples 1 to 3 described above. At 500° C., peaks characteristic of a diamond type structure were observed. Both Si and Ge have the same diamond type structure, and thus, no distinction may be made only from the X-ray diffraction spectra. In order to clarify this point, FIG. 9 shows X-ray diffraction spectra of the samples (Comparative Examples 2, 3, 5, and 6) formed by annealing the Ge single layer (Comparative Example 1) and annealing the Si single layer (Comparative Example 4). Peaks indicating crystallization may be clearly observed in the Ge layer at 500° C. On the other hand, no peak indicating crystallization is observed in the Si layer even at 700° C. Therefore, the peaks observed in the Si—Ge laminated film (Examples 1 to 3) shown in FIG. 8 may be identified to be due to crystallization of Ge.

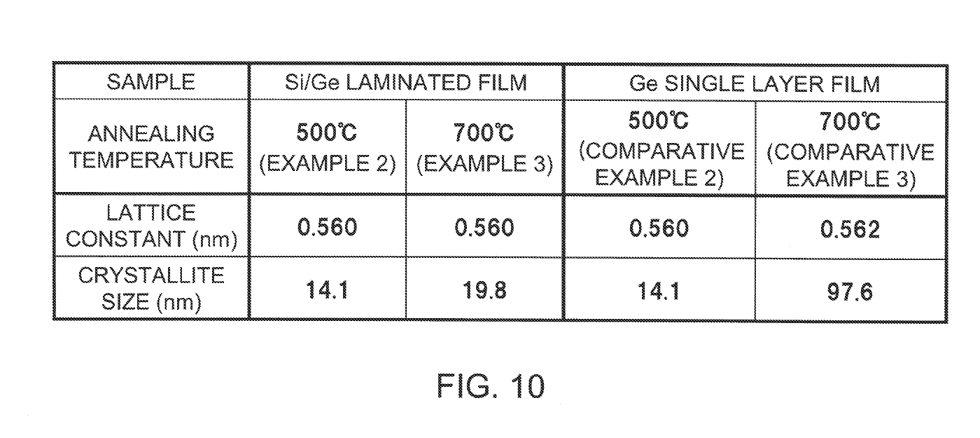

As a matter of fact, as shown in a table of FIG. 10, when comparison is made with the lattice constant of the Ge single layer film which was annealed at 500° C. (Comparative Example 5), it can be seen that peaks observed in the sample obtained by heating the Si—Ge laminated film to 500° C. were due to crystallized Ge. Further, with regard to the Si single layer films of Comparative Examples 7 to 9, no peak was confirmed even when annealing was carried out at 700° C. This result supports the above-mentioned result of Raman spectra. Further, when paying attention to the crystallite size of Ge, a Ge crystallite grew to 100 nm at 700° C. in the Ge single layer film, while a Ge crystallite grew only to about 20 nm in the Si—Ge laminated film. This suggests that diffusion of atoms in the Si layer is less liable to occur in the Si—Ge laminated film, and thus, crystal growth of Ge is prevented. With reference to FIG. 6, when heating to 700° C. is carried out, it appears that change is occurring in the vicinity of the surface, but it may be determined that the contribution thereof is small when seen from the entire Si—Ge laminated film.

It is found that, in this way, the structure obtained in Example 2 is the structure presented in this invention (on the right side of FIG. 1).

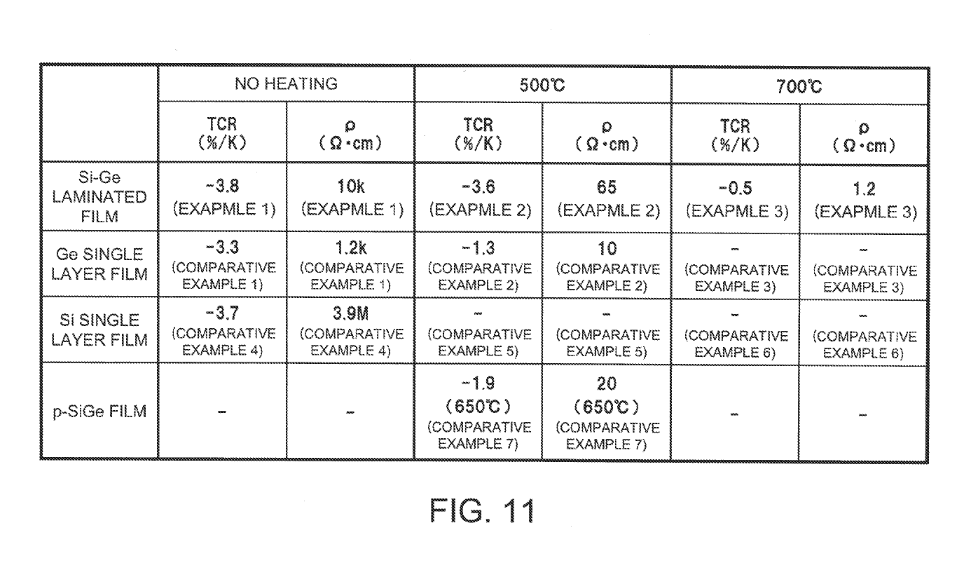

FIG. 11 is a table of the results of electrical measurement of the samples. In the electrical measurement, the resistivities of the respective samples differ greatly, and thus, optimum values of current for the respective samples were applied and the temperature change (−10 to 50° C.) was measured with respect to the voltage values. An infrared sensor material is required to have a TCR with a large absolute value and to have a low resistivity ρ. When comparison is made with films which were formed by sputtering and which were not heated, it can be confirmed that, with regard to the single layer films, while the Ge single layer film has a large TCR and a relatively low resistivity, the Si single layer film has a large TCR and a considerably high resistivity. The Si—Ge laminated film has a TCR which is near to that of the Si single layer film and has a resistivity which is near to that of the Ge single layer film, and it is found that the Si—Ge laminated film inherits good properties of the Ge single layer film and the Si single layer film. However, the resistivity is at a level of kΩ·cm, and thus, it cannot be said that the resistivity is sufficiently low. With regard to the samples formed by annealing at 500° C., in the Ge single layer film, the resistivity was lowered to 10 Ω·cm, but the TCR also decreased to −1.3%/K. On the other hand, in the Si single layer film, the resistivity became too high and the measurement could not be made. However, with regard to the Si—Ge film, while the TCR stays large, the resistivity reduces, and it may be confirmed that the performance of the Si—Ge film significantly exceeds the performance of the p-SiGe film 42 the specifications of which are substantially the same as those of a commercialized film. However, when the Si—Ge laminated film is annealed to 700° C., although the resistivity is considerably lowered, the TCR also considerably reduces. From the result, it can be said that raising the temperature to 700° C. is not preferred. Specifically, the optimum annealing temperature is at least in a range of 550° C. or lower.

As described above, by using the structure and the method according to this invention, an infrared sensor material optimum for an infrared sensor may be obtained.

Next, effects of the examples of this invention are described.

According to the examples of this invention, the Si layer and the Ge layer are alternately laminated, and thus, a uniform film may be formed even on a wafer having a large diameter. Further, by carrying out annealing treatment at a low temperature of 500° C. or lower, the Ge layer may be microcrystallized on a priority basis, and the resistivity may be lowered without reducing the TCR. Therefore, it is not necessary to extremely raise the process temperature, and other portions forming the device are less affected. Further, distortion caused by alternate dissolving of Si and Ge is suppressed, and thus, a thin film in which the extent of inside distortion is small and which is less liable to deform due to heat or the like may be formed, and the design accuracy of the infrared sensor device may be improved.

While the invention has been particularly shown and described with reference to the exemplary embodiments (and examples), the invention is not limited to these embodiments. It will be understood by those of ordinary skill in the art that various changes in form and details may be made therein without departing from the sprit and scope of the present invention as defined by the claims.

This application is based upon and claims the benefit of priority from Japanese Patent Application No. 2010-101692, filed on Apr. 27, 2010, the disclosure of which is incorporated herein in its entirety by reference.

### REFERENCE SIGNS LIST

1 quartz substrate
10 sample surface
21 amorphous Ge layer (a-Ge layer)
22 polycrystalline Ge layer (p-Ge layer)
31 amorphous Si layer (a-Si layer)
41 amorphous SiGe layer (a-SiGe layer)
42 polycrystalline SiGe layer (Cp-SiGe layer)
51 conductor
52 indium joining portion (In joining portion)

1. A Si—Ge laminated thin film, comprising at least one Si layer and at least one Ge layer, which are alternately laminated on a substrate,
wherein:
the Si layer and the Ge layer each have a thickness in a range of 5 to 500 nm;
the Si layer is amorphous and only the Ge layer is crystallized; and
an average crystallite size of Ge in the Ge layer is 20 nm or less.

2. The Si—Ge laminated thin film according to claim 1, wherein the Si layer and the Ge layer are alternately laminated by sputtering.

3. The Si—Ge laminated thin film according to claim 2, wherein the Si layer and the Ge layer are laminated with a substrate temperature being set at room temperature.

4. The Si—Ge laminated thin film according to claim 1, wherein the Si—Ge laminated thin film is formed by carrying out annealing treatment in an inert gas.

5. The Si—Ge laminated thin film according to claim 4, wherein the annealing treatment is carried out at a temperature of 550° C. or lower.

6. The Si—Ge laminated thin film according to claim 2, wherein the Si layer and the Ge layer are laminated with a substrate temperature being set at 200 to 550° C.

7. An infrared sensor material comprising the Si—Ge laminated thin film according to claim 1.

8. An infrared sensor device comprising the infrared sensor material according to claim 7.

9. An infrared sensor comprising the infrared sensor device according to claim 8, the infrared sensor device comprising infrared sensor devices arranged in a form of a two-dimensional array.

10. An infrared image sensor comprising the infrared sensor according to claim 9.
